(19) United States
(12) Patent Application Publication
(10) Pub. No.: US 2020/0375056 A1
(43) Pub. Date: Nov. 26, 2020

(54) FLEXIBLE MID-CHASSIS EXTENSION MODULE

(71) Applicant: Dell Products L.P., Round Rock, TX (US)

(72) Inventors: Robert B. CURTIS, Georgetown, TX (US); Stuart Allen BERKE, Austin, TX (US)

(73) Assignee: Dell Products L.P., Round Rock, TX (US)

(21) Appl. No.: 16/422,600

(22) Filed: May 24, 2019

(51) Int. Cl. H05K 7/14; G06F 1/20; H05K 7/02; H05K 7/20

(52) U.S. Cl. CPC H05K 7/1488; H05K 7/20945; H05K 7/026; G06F 1/20

(57) ABSTRACT

An information handling system chassis may include a first chassis module for housing a first set of information handling resources of an information handling system, a second chassis module for housing a second set of information handling resources of the information handling system, the second chassis module having second mechanical features for mechanically coupling to first mechanical features of the first chassis module, and a mid-chassis extension module having third mechanical features for mechanically coupling to the first mechanical features of the first chassis module and having fourth mechanical features for mechanically coupling to the second mechanical features of the second chassis module in order to mechanically couple the mid-chassis extension module between the first chassis module and the second chassis module, the mid-chassis extension module further comprising a third set of information handling resources with functionality different from that of the first set of information handling resources and the second set of information handling resources.

### TECHNICAL FIELD

The present disclosure relates to modular information handling systems. More specifically, embodiments of the disclosure provide systems and methods for providing a flexible mid-chassis extension module for an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As information handling system servers continue to see more demands for processors, memory, storage device, input/output (I/O) adapters, power supplies, batteries, and other features, it has been increasingly difficult to provide an optimized chassis and feature set which provides the necessary flexibility without being overly cost burdened to users who do not require or desire a full feature set for their specific desired configuration.

### SUMMARY

In accordance with the teachings of the present disclosure, the disadvantages and problems associated with traditional inflexibility in information handling system chassis size have been substantially reduced or eliminated.

In accordance with embodiments of the present disclosure, an information handling system chassis may include a first chassis module for housing a first set of information handling resources of an information handling system, a second chassis module for housing a second set of information handling resources of the information handling system, the second chassis module having second mechanical features for mechanically coupling to first mechanical features of the first chassis module, and a mid-chassis extension module having third mechanical features for mechanically coupling to the first mechanical features of the first chassis module and having fourth mechanical features for mechanically coupling to the second mechanical features of the second chassis module in order to mechanically couple the mid-chassis extension module between the first chassis module and the second chassis module, the mid-chassis extension module further comprising a third set of information handling resources with functionality different from that of the first set of information handling resources and the second set of information handling resources.

In accordance with these and other embodiments of the present disclosure, a mid-chassis extension module may include third mechanical features for mechanically coupling to first mechanical features of a first chassis module of an information handling system chassis, the first chassis module for housing a first set of information handling resources of an information handling system. The mid-chassis module may also include a fourth mechanical features for mechanically coupling to second mechanical features of a second chassis module of the information handling system chassis in order to mechanically couple the mid-chassis extension module between the first chassis module and the second chassis module, the second chassis module for housing a second set of information handling resources of the information handling system, and wherein the second mechanical features are configured to couple to the first mechanical features of the first chassis module. The mid-chassis module may also include a third set of information handling resources with functionality different from that of the first set of information handling resources and the second set of information handling resources.

In accordance with these and other embodiments of the present disclosure, a method may include mechanically coupling a first chassis module for housing a first set of information handling resources of an information handling system to a mid-chassis extension module, wherein such coupling comprises mechanically coupling third mechanical features of the mid-chassis extension module to first mechanical features of the first chassis module. The method may also include mechanically coupling a second chassis module for housing a second set of information handling resources of the information handling system to the mid-chassis extension module, wherein such coupling comprises mechanically coupling fourth mechanical features of the mid-chassis extension module to second mechanical features of the first chassis module, such that the mid-chassis extension module is coupled between the first chassis module and the second chassis module. The mid-chassis extension module may include a third set of information handling resources with functionality different from that of the first set of information handling resources and the second set of information handling resources.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates an elevation view of an information handling system chassis, in accordance with embodiments of the present disclosure;

FIG. 1B illustrates an isometric perspective view of an information handling system chassis, in accordance with embodiments of the present disclosure; and

FIG. 2 illustrates an isometric perspective view of a flexible mid-chassis extension module, in accordance with embodiments of the present disclosure.

### DETAILED DESCRIPTION

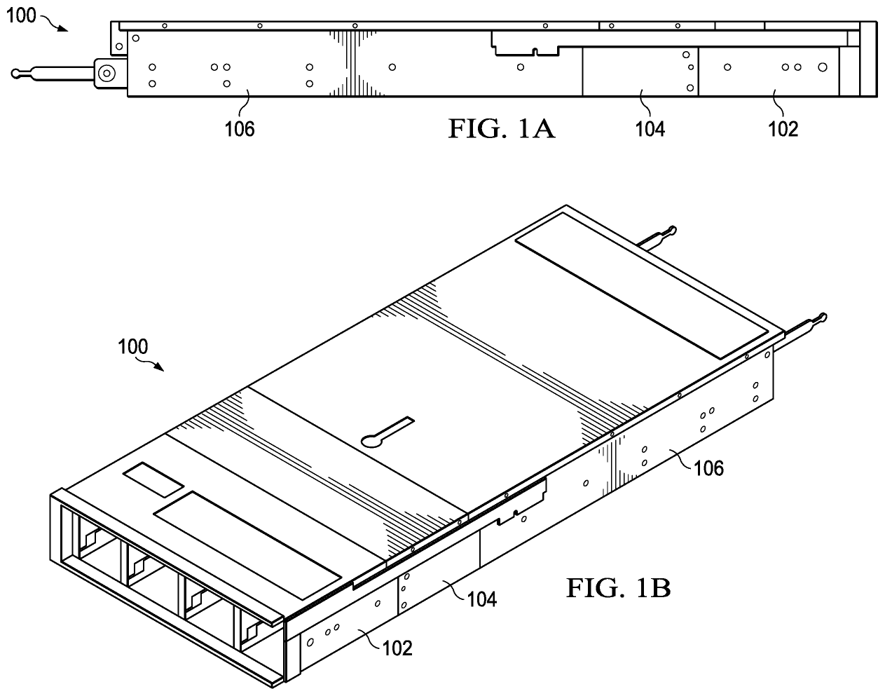

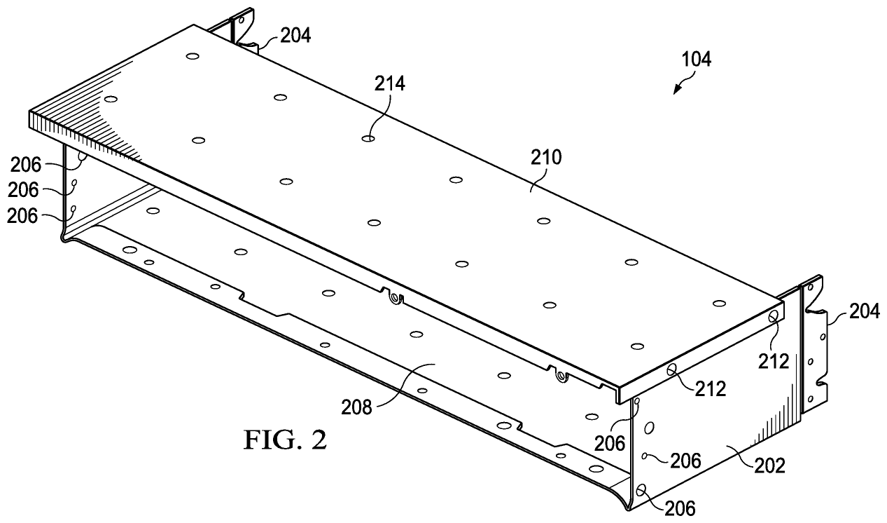

Preferred embodiments and their advantages are best understood by reference to FIGS. 1A, 1B, and 2, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

In this disclosure, the term “information handling resource” may broadly refer to any component system, device or apparatus of an information handling system, including without limitation processors, buses, memories, input-output devices and/or interfaces, storage resources, network interfaces, motherboards, electro-mechanical devices (e.g., fans), displays, and power supplies.

FIGS. 1A and 1B illustrate different views of an information handling system chassis 100, in accordance with embodiments of the present disclosure. In particular, FIG. 1A illustrates an elevation view of information handling system chassis 100, while FIG. 1B illustrates an isometric perspective view of information handling system chassis 100. Chassis 100 may be an enclosure that serves as a container for various information handling resources, and may be constructed from steel, aluminum, plastic, and/or any other suitable material. Although the term “chassis” is used, chassis 100 may also be referred to as a sled, case, cabinet, tower, box, enclosure, and/or housing. In some embodiments, chassis 100 may comprise a modular component (e.g., a sled or drawer) that may be easily inserted into and/or removed from a larger enclosure (e.g., a tower or rack) configured to receive a plurality of chassis 100.

As shown in FIGS. 1A and 1B, chassis 100 may comprise a front module 102 mechanically coupled to a mid-chassis extension module 104, which may in turn be mechanically coupled to a rear module 106. Each of front module 102, mid-chassis extension module 104, and rear module 106 may be an enclosure that serves as a container for various information handling resources, and may be constructed from steel, aluminum, plastic, and/or any other suitable material. However, front module 102, mid-chassis extension module 104, and rear module 106 may be configured to house different types of information handling resources. For example, in some embodiments, front module 102 may comprise a storage module configured to house one or more storage resources (e.g., hard disk drives) and rear module 106 may comprise a compute module configured to house one or more processors, memory modules, I/O adapters, and/or other “host system components” which may or may not be populated on a motherboard. Accordingly, mid-chassis extension module 104 may be a “flexible” component wherein mid-chassis extension module 104 may be configured to house components in order to customize a desired functionality within chassis 100. For example, in some embodiments, mid-chassis extension module 104 may comprise a cooling module configured to house enhanced air cooling components such as air movers (e.g., fans), heatsinks, and/or liquid cooling hardware (e.g., pump, manifold, heat exchanger, fluidic tubing, etc.). Cooling processors and other heat-generating components may pose a significant challenge, a challenge that may increase as processing capacity increases and processors generate increasing levels of heat. To provide adequate cooling for heat-generating components, thermal solutions (e.g., heatsinks and other heat-rejecting media) may need to grow in surface area. Traditionally, thermal solution growth has been constrained to the footprint of a processor base keep-in with little to no allowance for increased heatsink size. Volume available for increased air mover size (and thus fan performance) has also remained constant over many generations. Accordingly, a mid-chassis extension module 104 may allow for significant increases in the air mover and/or heatsink sizes to enable cooling of future hardware solutions.

As another example, in some embodiments, mid-chassis extension module 104 may comprise an acoustics/dynamics module configured to house acoustic and vibrational dampening structures that may reduce system sound power levels, chassis vibration, and/or aeroacoustical impacts on storage resources having rotating media. A primary challenge that continues to grow more difficult over time is the aeroacoustical impact that high-speed air movers have on storage resources implemented with rotational media (e.g., hard-disk drives). The acoustical output of these air movers may impact the ability of rotational-media storage resources to properly read/write data to the disk resulting in reduced storage resource throughput and/or the risk of data loss. Projections for future generations of hard-disk drives show that the susceptibility of the hard-disk drives to this acoustical energy will likely become worse over time resulting in the requirement for air mover speeds to be cut in half from their existing levels. This reduced air mover speed requirement may counter to what is required to cool processors and other components which generate increasing levels of heat. Thus an alternate cooling solution may be required. Mid-chassis extension module 104 may allow for additional chassis volume that may be used for components that block and/or absorb the acoustical energy that impacts rotational-media storage resources and/or other devices. Such components within mid-chassis extension module 104 may allow dense rotational-media storage resources to co-exist with extreme heat-generating components and high-speed air movers.

As a further example, in some embodiments, mid-chassis extension module 104 may comprise a backup power module that may include backup sources of electrical energy (e.g., uninterruptible power supplies, batteries, etc.), that may activate in the event of alternating current power failures within chassis 100.

As an additional example, mid-chassis extension module 104 may comprise an auxiliary I/O module (e.g., a field-programmable gate array) that may provide I/O connectivity between a processing core of chassis 100 and one or more peripheral devices of chassis 100.

FIG. 2 illustrates an isometric perspective view of flexible mid-chassis extension module 104, in accordance with embodiments of the present disclosure. As shown in FIG. 2, mid-chassis extension module 104 may include a base housing 202 and cover 210 which may be mechanically coupled to one another via coupling features 212 (e.g., screws or other fasteners and corresponding holes). As also shown in FIG. 2, mid-chassis extension module 104 may include features 204 (e.g., flanges, guides, mounting holes, etc.) configured to mechanically couple to one of front module 102 and rear module 106 and features 206 (e.g., guides, mounting holes, etc.) to mechanically couple to the other of front module 102 and rear module 106 and features 204. Corresponding mechanical coupling features of front module 102 and rear module 106 may be coupled to mechanically mate to one another in the absence of mid-chassis extension module 104. Also as depicted in FIG. 2, mid-chassis extension module 104 may include a plurality of features 208 and 214 for mechanically coupling components housed therein to mid-chassis extension module 104.

Thus, using the methods and systems described herein, mid-chassis extension module 104 may provide a way to increase the length of a chassis as required for a particular feature set. Traditionally, addition of such a feature set would be implemented in another chassis. Mid-chassis extension module 104 thus allows for additional flexibility, reuse, and cost-optimization of a base chassis comprising front module 102 and rear module 106.

Mid-chassis extension module 104 may also enable increased chassis length and/or volume for enhancements of chassis capabilities and/or features (e.g., as a cooling module, acoustics/dynamics module, backup power module, or an auxiliary I/O module).

In some embodiments, chassis 100 may support multiple mid-chassis extension modules 104 coupled to one another between front module 102 and rear module 106.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. An information handling system chassis comprising:
a first chassis module for housing a first set of information handling resources of an information handling system;
a second chassis module for housing a second set of information handling resources of the information handling system, the second chassis module having second mechanical features that are coupleable to first mechanical features of the first chassis module; and
a mid-chassis extension module having third mechanical features for mechanically coupling to the first mechanical features of the first chassis module and having fourth mechanical features for mechanically coupling to the second mechanical features of the second chassis module in order to mechanically couple the mid-chassis extension module between the first chassis module and the second chassis module, the mid-chassis extension module further comprising a third set of information handling resources with functionality different from that of the first set of information handling resources and the second set of information handling resources;
wherein the mid-chassis extension module comprises a cooling module that includes at least one heatsink thermally coupled to the first set of information handling resources in the first chassis module.

2. The information handling system chassis of claim 1, wherein the mid-chassis extension module is selected from a plurality of different mid-chassis extension modules, each of the plurality of different mid-chassis extension modules differing from one another in one or more of length, volume, and functionality of the third set of information handling resources.

3. (canceled)

4. The information handling system chassis of claim 1, wherein the mid-chassis extension module comprises an acoustics/dynamics module wherein the third set of information handling resources comprises a plurality of information handling resources for reducing at least one of acoustical energy and vibrational energy of the information handling system chassis.

5. The information handling system chassis of claim 1, wherein the mid-chassis extension module comprises a backup power module wherein the third set of information handling resources comprises at least one of a battery and an uninterruptable power supply.

6. The information handling system chassis of claim 1, wherein the mid-chassis extension module comprises an auxiliary processing module wherein the third set of information handling resources comprises an input/output interface between a processor of the first chassis module and peripheral devices of the information handling system chassis.

7. A mid-chassis extension module comprising:
third mechanical features for mechanically coupling to first mechanical features of a first chassis module of an information handling system chassis, the first chassis module for housing a first set of information handling resources of an information handling system;
fourth mechanical features for mechanically coupling to second mechanical features of a second chassis module of the information handling system chassis in order to mechanically couple the mid-chassis extension module between the first chassis module and the second chassis module, the second chassis module for housing a second set of information handling resources of the information handling system, and wherein the second mechanical features are coupleable to the first mechanical features of the first chassis module; and
a third set of information handling resources with functionality different from that of the first set of information handling resources and the second set of information handling resources;
wherein the mid-chassis extension module comprises a cooling module that includes at least one heatsink thermally coupled to the first set of information handling resources in the first chassis module.

8. The mid-chassis extension module of claim 7, wherein the first chassis module and the second chassis module are configured to mechanically couple to a plurality of different mid-chassis extension modules, each of the plurality of different mid-chassis extension modules differing from one another in one or more of length, volume, and functionality of the third set of information handling resources.

9. (canceled)

10. The mid-chassis extension module of claim 7, wherein the mid-chassis extension module comprises an acoustics/dynamics module wherein the third set of information handling resources comprises a plurality of information handling resources for reducing at least one of acoustical energy and vibrational energy of the information handling system chassis.

11. The mid-chassis extension module of claim 7, wherein the mid-chassis extension module comprises a backup power module wherein the third set of information handling resources comprises at least one of a battery and an uninterruptable power supply.

12. The mid-chassis extension module of claim 7, wherein the mid-chassis extension module comprises an auxiliary processing module wherein the third set of information handling resources comprises an input/output interface between a processor of the first chassis module and peripheral devices of the information handling system chassis.

13. A method comprising:
mechanically coupling a first chassis module for housing a first set of information handling resources of an information handling system to a mid-chassis extension module, wherein such coupling comprises mechanically coupling third mechanical features of the mid-chassis extension module to first mechanical features of the first chassis module; and
mechanically coupling a second chassis module for housing a second set of information handling resources of the information handling system to the mid-chassis extension module, wherein such coupling comprises mechanically coupling fourth mechanical features of the mid-chassis extension module to second mechanical features of the second chassis module, such that the mid-chassis extension module is coupled between the first chassis module and the second chassis module, wherein the second mechanical features are also coupleable to the first mechanical features;
wherein the mid-chassis extension module comprises a third set of information handling resources with functionality different from that of the first set of information handling resources and the second set of information handling resources; and
wherein the mid-chassis extension module comprises a cooling module that includes at least one heatsink thermally coupled to the first set of information handling resources in the first chassis module.

14. The method of claim 13, wherein the first chassis module and the second chassis module are configured to mechanically couple to a plurality of different mid-chassis extension modules, each of the plurality of different mid-chassis extension modules differing from one another in one or more of length, volume, and functionality of the third set of information handling resources.

15. (canceled)

16. The method of claim 13, wherein the mid-chassis extension module comprises an acoustics/dynamics module wherein the third set of information handling resources comprises a plurality of information handling resources for reducing at least one of acoustical energy and vibrational energy of the information handling system chassis.

17. The method of claim 13, wherein the mid-chassis extension module comprises a backup power module wherein the third set of information handling resources comprises at least one of a battery and an uninterruptable power supply.

18. The method of claim 13, wherein the mid-chassis extension module comprises an auxiliary processing module wherein the third set of information handling resources comprises an input/output interface between a processor of the first chassis module and peripheral devices of the information handling system chassis.
